(19) United States
(12) Patent Application Publication
(10) Pub. No.: US 2009/0032104 A1
(43) Pub. Date: Feb. 5, 2009

(54) DYE-SENSITIZED SOLAR CELL HAVING IMPROVED ENERGY CONVERSION EFFICIENCY AND METHOD OF FABRICATING THE SAME

(75) Inventors: Seung-Yup Lee, Gyeongsangbuk-do (KR); Yong-Seok Jun, Daejeon (KR); Man-Gu Kang, Daejeon (KR); Ho-Gyeong Yun, Seoul (KR); Jong-Hyeok Park, Daejeon (KR); Hunkyun Pak, Daejeon (KR); Jong-Dae Kim, Daejeon (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon (KR)

(21) Appl. No.: 12/118,464

(22) Filed: May 9, 2008

(30) Foreign Application Priority Data
Aug. 2, 2007 (KR) 10-2007-0077764

(51) Int. Cl. H01L 31/04; H01L 31/028; H01L 31/18; H01L 31/0296

(52) U.S. Cl. 136/261; 136/252; 136/265; 438/98; 257/E31.003

(57) ABSTRACT

Provided are a dye-sensitized solar cell with increased energy conversion efficiency, and a method of fabricating the same. The dye-sensitized solar cell is provided with a semiconductor electrode layer including hollow-shaped semiconductor particles and a dye layer adsorbed on the surface of the semiconductor electrode layer, and the dye layer is adsorbed on the outer and inner surfaces of the semiconductor particles.

### CROSS-REFERENCE TO RELATED APPLICATIONS

This U.S. non-provisional patent application claims priority under 35 U.S.C. § 119 of Korean Patent Application No. 10-2007-77764, filed on Aug. 2, 2007, the entire contents of which are hereby incorporated by reference.

### BACKGROUND OF THE INVENTION

The present invention disclosed herein relates to a dye-sensitized solar cell and a method of fabricating the same, and more particularly, to a dye-sensitized solar cell having improved energy conversion efficiency and a method of fabricating the same.

The present invention has been derived from research undertaken as a part of the information technology (IT) development business by the Ministry of Information and Communication and Institute for Information Technology Advancement of the Republic of Korea [Project management No.: 2006-S-006-02, Project title: component module for ubiquitous terminal].

A solar cell is a photovoltaic energy conversion system that converts light energy radiated from the sun to electrical energy. Silicon solar cells widely used today employ a p-n junction diode formed in silicon for photovoltaic energy conversion.

However, to prevent premature recombination of electrons and holes, the silicon must have a high degree of purity and less defects. Since these technical requirements cause an increase in material cost, silicon solar cells have a high fabrication cost per watt.

Moreover, because only photons, which have an energy level greater than a bandgap, contribute to generating current, silicon used for silicon solar cells is doped to have a lower bandgap. However, due to the lowered bandgap, electrons excited by blue light or ultraviolet light become overly energized, and are consumed to generate heat rather than electrical current.

Also, a p-type layer must be sufficiently thick to increase photon capturing probability; however, because the thick p-type layer increases the probability of excited electrons recombining with holes before they reach a p-n junction, the efficiency of silicon solar cells remains low in an approximate range of 7% to 15%.

In 1991, Michael Gratzel, Mohammad K. Nazeeruddin, and Brian O'Regan disclosed a Dye-sensitized Solar Cell (DSC), based on the photosynthesis reaction principle, and known as the “Gratzel cell” in U.S. Pat. No. 5,350,644, which is hereby incorporated by reference in its entirety. A dye-sensitized solar cell, which employs the Gratzel model as a prototype, is a photoelectrochemical system that employs a dye material and a transition metal oxide layer instead of a p-n junction diode for photovoltaic energy conversion. Specifically, a dye-sensitized solar cell includes a semiconductor electrode with the dye material and transition metal oxide material, a counter electrode coated with platinum or carbon, and an electrolyte between the electrodes.

Since the material used in such a dye-sensitized solar cell is inexpensive and the fabrication method is simple, fabrication costs of the dye-sensitized solar cells are lower than those of silicon solar cells. Furthermore, because a dye-sensitized solar cell has an energy conversion efficiency similar to that of a silicon solar cell, it has a lower fabrication cost per output watt than a silicon solar cell. In particular, in the aftermath of extensive research conducted recently on materials, dye-sensitized solar cells are projected to be capable of satisfying various industrial requirements such as improved energy conversion efficiency and reduced fabrication costs.

### SUMMARY OF THE INVENTION

The present invention provides a dye-sensitized solar cell capable of providing increased energy conversion efficiency.

The present invention also provides a method of fabricating a dye-sensitized solar cell capable of providing increased energy conversion efficiency.

Embodiments of the present invention provide dye-sensitized solar cells with an increased surface area of a dye layer. The dye-sensitized solar cell includes a semiconductor electrode layer including hollow-shaped semiconductor particles, and a dye layer adsorbed onto a surface of the semiconductor electrode layer. Here, the dye layer may be adsorbed onto outer surfaces and inner surfaces of the semiconductor particles.

In some embodiments, the semiconductor particles may have shapes including at least one of a hollow sphere, a hollow hemisphere, and a hollow sphere with a through-hole, the semiconductor particles may respectively have a diameter ranging from about 10 nm to about 60 nm, each of the semiconductor particles may include at least one through-hole communicating the outer surface and the inner surface thereof, and the through-hole may have a diameter greater than sizes of dye molecules forming the dye layer.

In other embodiments, the semiconductor electrode layer may be formed of at least one of titanium oxide (TiO₂), tin oxide (SnO₂), zirconium oxide (ZrO₂), silicon oxide (SiO₂), magnesium oxide (MgO), niobium oxide (Nb₂O₅), and zinc oxide (ZnO). Also, the dye layer may be at least one of ruthenium complexes including N719, N712, Z907, Z910, and K19.

In still other embodiments, the dye-sensitized solar cell may further include a lower electrode structure disposed under the semiconductor electrode layer, an upper electrode structure disposed over the semiconductor electrode layer, and an electrolyte interposed between the upper electrode structure and the semiconductor electrode layer. Here, the lower electrode structure may include a lower substrate, and a lower transparent electrode disposed on the lower substrate and contacting the semiconductor electrode layer, and the upper electrode structure may include an upper substrate, an upper transparent electrode disposed on the upper substrate and facing the semiconductor electrode layer, and a catalyst layer interposed between the upper transparent electrode and the electrolyte.

In other embodiments of the present invention, methods for fabricating a dye-sensitized solar cell with an increased surface area of a dye layer are provided. The methods include forming a lower electrode structure, forming a semiconductor electrode layer including hollow-shaped semiconductor particles on the lower electrode structure, forming a dye layer on a surface of the semiconductor electrode layer, forming an upper electrode structure on a resultant structure including the dye layer to face the semiconductor electrode layer, and injecting an electrolyte between the semiconductor electrode layer and the upper electrode structure.

In some embodiments, the forming of the semiconductor electrode layer may include forming the hollow-shaped semiconductor particles with at least one of methods employing a template, micro-emulsion, hydrolysis, and sol-gel processing.

In other embodiments, the forming of the semiconductor electrode layer may further include forming at least one through-hole in each of the semiconductor particles to communicate inner surfaces and outer surfaces of the semiconductor particles, the through-holes having diameters greater than dye molecules forming the dye layer, and the dye layer is adsorbed onto the outer surfaces of the semiconductor particles and the inner surfaces of the semiconductor particles through the through-holes. The forming of the through-holes may include employing at least one of heat treating, rapid drying, supersonic treating, and physical pressing techniques.

In still other embodiments, the semiconductor particles may have shapes including at least one of a hollow sphere, a hollow hemisphere, and a hollow sphere with a through-hole. The semiconductor electrode layer may be formed of at least one of titanium oxide (TiO₂), tin oxide (SnO₂), zirconium oxide (ZrO₂), silicon oxide (SiO₂), magnesium oxide (MgO), niobium oxide (Nb₂O₅), and zinc oxide (ZnO). The semiconductor particles may respectively have a diameter ranging from about 10 nm to about 60 nm. The dye layer may be at least one of ruthenium complexes including N719, N712, Z907, Z910, and K19.

In even other embodiments, the forming of the semiconductor electrode layer may include forming spherical template particles, forming a semiconductor material layer on surfaces of the template particles, and forming voids in the semiconductor material layer through selectively removing the template particles. Here, the template particles may be formed of polystyrene.

In yet other embodiments, method may further include, after the forming of the semiconductor material layer, forming at least one through-hole in each of the semiconductor particles through employing at least one of a rapid thermal annealing process, a rapid drying process, a supersonic treatment process, and a physical pressing process, to communicate inner surfaces and outer surfaces of the semiconductor particles, wherein the through-holes have diameters greater than dye molecules forming the dye layer. Here, the forming of the through-holes through employing the rapid thermal annealing process may be performed at a temperature ranging from about 450° C. to 700° C.

According to the present invention, a semiconductor electrode layer includes hollow-shaped nanoparticles, and a dye layer is formed to cover the inner walls and the outer walls of the hollow-shaped nanoparticles. Accordingly, the area of the dye layer per unit volume of the dye-sensitized solar cell according to the present invention is increased over that of a typical solar cell. Thus, a dye-sensitized solar cell according to the present invention can have higher energy conversion efficiency than that of a typical solar cell.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view of a dye-sensitized solar cell according to an embodiment of the present invention;

FIG. 2 is a sectional view illustrating a semiconductor electrode layer of a dye-sensitized solar cell in more detail according to the present invention;

FIGS. 3 through 5 are perspective views illustrating a semiconductor electrode layer of a dye-sensitized solar cell in further detail according to the present invention; and

FIG. 6 is a flowchart illustrating a method for fabricating a dye-sensitized solar cell according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the figures, it will be understood that when a layer (or film) is referred to as being ‘on’ another layer or substrate, it can be directly on the other layer or substrate, or intervening layers may also be present. Further, it will be understood that the dimensions of layers and regions are exaggerated for clarity of illustration. In addition, in various embodiments of the present invention, while terms such as “first”, “second”, and “third” are used to describe various regions, layers, etc., these regions, layers, etc. should not restricted by said terms. The terms are used solely to differentiate one particular region or layer from another region or layer. Therefore, a layer referred to as a first layer in one embodiment may be referred to as a second layer in another embodiment. The respective embodiments described and exemplified herein include complementary embodiments thereof.

Hereinafter, an exemplary embodiment of the present invention will be described with the accompanying drawings.

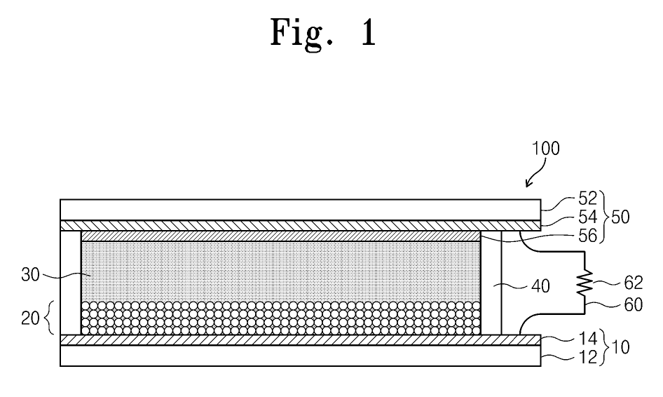

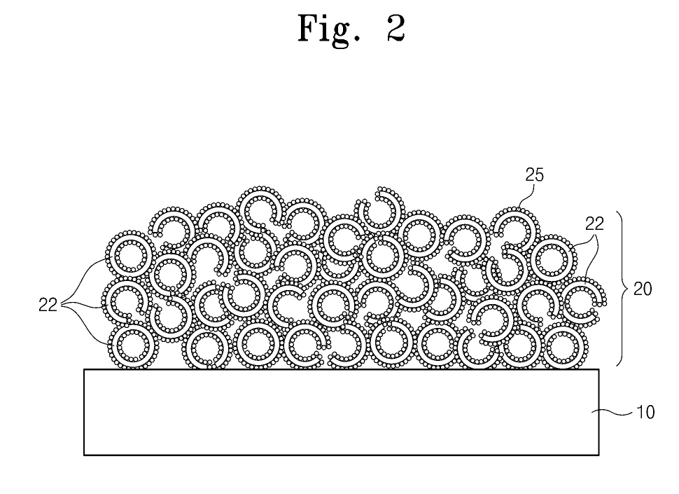

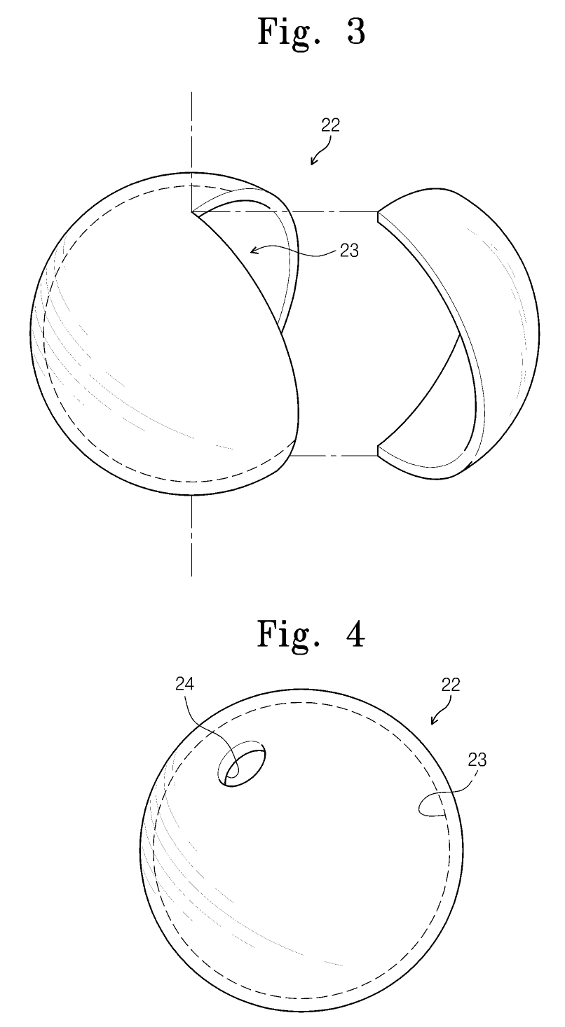

FIG. 1 is a sectional view of a dye-sensitized solar cell according to an embodiment of the present invention, FIG. 2 is a sectional view illustrating a semiconductor electrode layer of a dye-sensitized solar cell in more detail according to the present invention, and FIGS. 3 through 5 are perspective views illustrating a semiconductor electrode layer of a dye-sensitized solar cell in further detail according to the present invention.

Referring to FIGS. 1 and 2, a dye-sensitized solar cell 100 according to the present embodiment includes a lower electrode structure 10, an upper electrode structure 50, and a semiconductor electrode layer 20 interposed therebetween and contacting the lower electrode structure 10. Further, an electrolyte 30 is interposed between the upper electrode structure 50 and the semiconductor electrode layer 20, and a dye layer 25 with dye molecules is formed on the surface of the semiconductor electrode layer 20.

The lower electrode structure 10 includes a lower glass substrate 12 and a lower electrode layer 14 coated on a surface of the lower glass substrate 12, and the upper electrode structure 50 includes an upper glass substrate 52 and an upper electrode layer 54 coated on a surface of the upper glass substrate 52. Here, the lower electrode layer 14 on the lower electrode structure 10 and the upper electrode layer 54 on the upper electrode structure 50 are disposed facing each other. The lower electrode layer 14 and the upper electrode layer 54 may be formed of a transparent conductive material. For example, the lower electrode layer 14 may be formed of at least one of Indium Tin Oxide (ITO), SnO₂, SnO₂:F (FTO), ZnO, and carbon nanotubes, and the upper electrode layer 54 may be formed similarly of at least one of ITO, SnO₂, FTO, ZnO, and carbon nanotubes. Furthermore, the upper electrode structure 50 may further include a catalyst layer 56, which is disposed on the upper electrode layer 54 and contacts the electrolyte. The catalyst layer 56 catalyzes a reducing process of a triiodide compound to an iodide compound, and according to one embodiment, the catalyst layer 56 may be a platinum (Pt) layer, which is coated on the upper electrode layer 54 with an amount of 5-10 μg/cm².

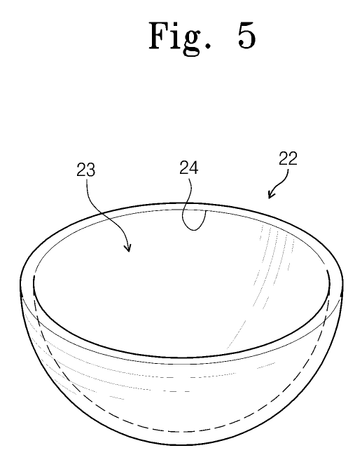

The semiconductor electrode layer 20, as illustrated in FIGS. 2 through 5, includes hollow-shaped semiconductor particles 22. That is, each of the semiconductor particles 22 has a void 23 defined by its inner wall. According to an embodiment of the present invention, each of the semiconductor particles 22 may be formed to have a shape of a hollow sphere (or spherical shell), as shown in FIG. 3. According to another embodiment of the present invention, each of the semiconductor particles 22 may be formed to have a shape of a hollow sphere with at least one through-hole 24, as shown in FIG. 4. That is, the outer surface of the semiconductor particle 22 can be connected to the inner surface thereof through the through-hole 24. Here, the size and shape of the through-hole 24 may vary. For example, the size of the through-hole 24 may be substantially the same size as the maximum diameter between points on the inner surface of the semiconductor particle 22, in which case, the semiconductor particle 22 may have the shape of a hollow hemisphere, as shown in FIG. 5. The semiconductor particles 22 may be aggregations of fine particles with a size ranging from about several angstroms to several nanometers. Here, the through-holes 24 are naturally formed between the respective fine particles, and can provide a space for connecting the outer surface of the semiconductor particles 22 with the inner surface thereof.

The sizes of the respective semiconductor particles 22 may range between about 10 nm to about 60 nm, and the semiconductor particles 22 may be formed of one of various metal oxides containing transition metal oxide. For example, the semiconductor particles 22 may be one of titanium oxide (TiO₂), tin oxide (SnO₂), zirconium oxide (ZrO₂), silicon oxide (SiO₂), magnesium oxide (MgO), neobium oxide (Nb₂O₅), and zinc oxide (ZnO).

According to the present invention, since the semiconductor electrode layer 20 includes semiconductor particles 22 with the through-holes 24, the dye layer 25 may be formed to cover both the inner and outer surfaces of the semiconductor particles 22. During the process of forming the dye layer 25, the through-holes 24 provide passages through which the dye molecules forming the dye layer 25 can reach the inner surfaces of the semiconductor particles 22. To achieve this, the breadth of the through-holes 24 of the semiconductor particles 22 may be larger than the size of each dye molecule.

When sunlight is radiated on the dye layer 25, excited electrons are injected into the conduction band of the semiconductor electrode layer 20, and then transferred to the lower electrode layer 14. For this, the dye layer 25 may be a ruthenium complex. For example, the dye material may be N719 (Ru(dcbpy)2(NCS)2 containing 2 protons). However, at least one from various well-known dye materials may be used for forming a dye-sensitized solar cell of the present invention. For example, dye material such as N712, Z907, Z910, and K19 may be used for a dye-sensitized solar cell according to the present invention.

Since the dye layer 25 covers both the inner and outer surfaces of the semiconductor particles 22, a dye-sensitized solar cell according to the present invention has a larger area of dye layer per unit volume than conventional solar cells. Given that the dye layer 25 is a region in which the first process (i.e., electron excitation) for converting light energy to electrical energy occurs, the dye-sensitized solar cells according to the present invention may have higher energy conversion efficiency than conventional solar cells.

According to an embodiment of the present invention, the semiconductor electrode layer 20 may be formed of particles composed of hollow spherical nano-crystalline titanium oxide (hsnc TiO₂). Here, while the hsnc TiO₂ particles are each separately formed, they are each formed to physically contact at least one adjacent hsnc TiO₂ particle such that excited electrons are transferred to the lower electrode layer 14.

The electrolyte 30 may be a redox iodide electrolyte. According to an embodiment of the present invention, the electrolyte 30 may be an electrolyte of I₃⁻/I⁻ obtained by dissolving 0.7 M 1-vinyl-3-hexyl-imidazolium iodide, 0.1 M LiI, and 40 mM I₂ (Iodine) in 3-methoxypropionitrile. According to another embodiment of the present invention, the electrolyte 30 may be an acetonitrile electrolyte containing 0.6 M butylmethylimidazolium, 0.02 M I₂, 0.1 M guanidinium thiocyanate, and 0.5 M 4-tert-butylpyridine. However, one of various electrolytes not exemplarily mentioned above may be used as the electrolyte according to the present invention. For example, the electrolyte 30 may include alkylimidazolium iodides or tetra-alkyl ammoniumiodides. The electrolyte 30 may further include tert-butylpyridin (TBP), benzimidazole (BI), and N-Methylbenzimidazole (NMBI) as surface additives, and may use acetonitrile, propionitrile, or a mixed liquid of acetonitrile and valeronitrile as a solvent.

The excited electrons transferred through the semiconductor electrode layer 20 to the lower electrode layer 14 are transferred to the dye molecules through the upper electrode layer 54 and the electrolyte. Thus, the dye-sensitized solar cell continually generates electrical current through the above electron circulation system. For this circulation system of electrons, the upper electrode layer 54 and the lower electrode layer 14 may be connected through a predetermined interconnection structure 60, and a load 62 consuming energies of the electrons may be provided on the interconnection structure 60.

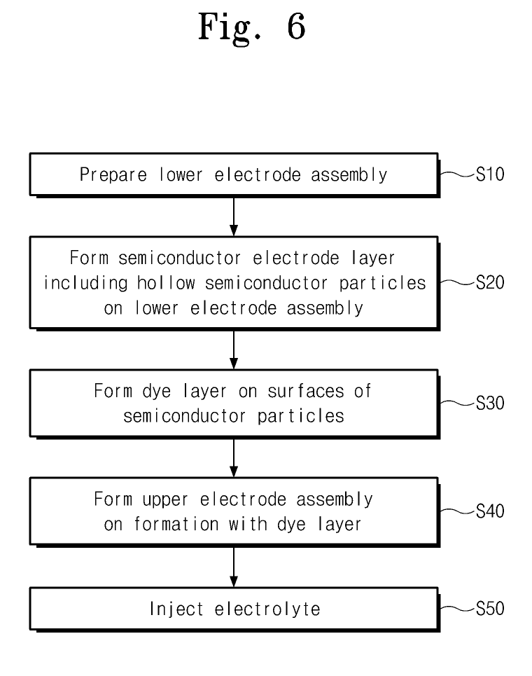

FIG. 6 is a flowchart illustrating a method for fabricating a dye-sensitized solar cell according to an embodiment of the present invention.

Referring to FIGS. 1 and 6, a lower electrode structure 10 is prepared in operation S10. The lower electrode structure 10 includes a lower glass substrate 12, and a lower electrode layer 14 coated on one side of the lower glass substrate 12. The lower electrode layer 14 may be at least one of ITO, SnO₂, FTO, ZnO, and carbon nanotubes.

Next, a semiconductor electrode layer 20 is formed on the lower electrode structure 10 in operation S20. The semiconductor electrode layer 20 may be one of metal oxides that include transition metal oxides. For example, the semiconductor electrode layer 20 may be one of titanium oxide (TiO₂), tin oxide (SnO₂), zirconium oxide (ZrO₂), silicon oxide (SiO₂), magnesium oxide (MgO), niobium oxide (Nb₂O₅), and zinc oxide (ZnO). Also, the semiconductor electrode layer 20 includes hollow-shaped semiconductor particles 22. That is, each of the semiconductor particles 22 has a void 23 defined by its inner wall. For example, the semiconductor particles 22 may have the shape of at least one of a hollow sphere (i.e., a spherical shell), a hollow sphere with at least one through-hole 24, and a hollow hemisphere as shown in FIGS. 2 through 5. Here, the through-hole 24 may be formed to connect the outer wall of the semiconductor particle 22 with the inner wall of the semiconductor particle 22, and the size and shape of the through-hole 24 may vary.

According to an embodiment of the present invention, the semiconductor electrode layer 20 may be formed of hollow spherical titanium oxide particles with respective through-holes having a size ranging from about 10 nm to about 60 nm, and may be coated at a thickness ranging from about 5 mm to 30 mm on the lower electrode structure 10. Here, the operation of forming the semiconductor electrode layer 20 may include coating a viscous colloid having hollow spherical TiO₂ nanoparticles on the lower electrode structure 10, and performing heat treating of the coated viscous colloid with a temperature ranging from about 450° C. to about 550° C. to leave the hollow spherical TiO₂ nanoparticles on the lower electrode structure 10.

Specifically, the preparation of the viscous colloid having hollow spherical titanium oxide nanoparticles may include preparing a TiO₂ nanoparticle powder, and then adding paste to the TiO₂ nanoparticle powder. Here, the paste may include at least one of polyethylenglycol and polyethyleneoxide. The hollow spherical TiO₂ nanoparticles may be formed in hollow spherical shapes by using at least one method from casting, micro-emulsion, hydrolysis, and sol-gel processing.

The method of forming the hollow spherical TiO₂ nanoparticles through casting includes first forming spherical template particles, and then forming a TiO₂ layer on the spherical template particles. Next, the template particles are removed using a predetermined solvent or through a heat treatment process to form hollow spherical titanium oxide particles. In one embodiment, the template particles may be formed of polyethylene, and the solvent for removing the template particles may be an organic solvent containing toluene. Also, the TiO₂ layer may be formed through hydrolysis of titanium tetraisopropoxide.

According to one embodiment, the process of removing the template particles may include performing a rapid thermal annealing of the template particles at a temperature ranging from between about 400° C. to about 700° C. In this case, the template particles and the TiO₂ layer formed on the surfaces thereof may be deformed or burst through thermal stress. In this way, the through-holes 24 of the semiconductor particles 22 may be formed, and the size and shape thereof may be variably controlled through the size and material type of the template particles, processing conditions of the rapid thermal annealing, the type of solvent and treatment used for removing the template particles, etc. Furthermore, the through-holes 24 may be formed using at least one of rapid drying, supersonic treatment, and physical pressing techniques.

The hollow spherical TiO₂ nanoparticles according to modified embodiments of the present invention may be formed through modifications of methods proposed by Arnout Imhof in the published paper entitled, “Preparation and Characterization of Titania-Coated Polystyrene Spheres and Hollow Titania Shells” (Langmuir, 2001, vol. 17, pp. 3579-3585), Huamin Kou et al. in the published paper entitled, “Fabrication of hollow ZnO microsphere with zinc powder precursor” (MATERIALS CHEMISTRY AND PHYSICS, 2006, vol. 99, pp 325-328), and Xia Zhang et al. in the published paper entitled, “Sonochemical Method for the Preparation of Hollow SnO2 Microspheres” (Chinese Journal of Chemistry, 2006, vol. 24, pp. 983-985).

Next, a dye layer 25 including dye molecules is formed on the surface of the semiconductor electrode layer 20 in operation S30. The forming of the dye layer 25 includes immersing the lower electrode structure 10 with the semiconductor electrode layer 20 formed thereon in an alcohol solution including dye for about 24 hours. Then, the lower electrode structure 10 with the semiconductor electrode layer 20 is drawn from the alcohol solution, and then, cleaning the lower electrode structure 10 with alcohol may be further performed. Through this process, the dye molecules may be formed covering both the inner and outer walls of the semiconductor particles 22, as illustrated in FIG. 2.

The dye layer 25 may include a ruthenium complex. For example, the dye may be N719 (Ru(dcbpy)2(NCS)₂ containing 2 protons). However, at least one of various dye materials not exemplary described herein may be used for the dye-sensitized solar cell of the present invention. For example, widely-known dyes such as N712, Z907, Z910, and K19 may be used for the dye-sensitized solar cell of the present invention.

Next, in operation S40, an upper electrode structure 50 is attached to the upper portion of the semiconductor electrode layer 20 on which the dye layer 25 is applied. The upper electrode structure 50 includes an upper glass substrate 52, and an upper electrode layer 54 coated on a surface of the upper glass substrate 52. The upper electrode layer 54 may be at least one of ITO, SnO₂, FTO, ZnO, and carbon nanotubes. Furthermore, a catalyst layer 56 may be further formed on the upper electrode layer 54. According to an embodiment, the catalyst layer 56 may be a platinum layer deposited on the upper electrode layer 54 at a thickness ranging from about 5 to about 10 μg/cm².

The upper electrode structure 50 is attached so that the catalyst layer 56 and the upper electrode layer 54 face the semiconductor electrode layer 20. This attaching operation may include forming a polymer layer 40 between the lower electrode structure 10 and the upper electrode structure 50, and compressing the lower and upper glass substrates 12 and 52 at a temperature ranging from about 100° C. to about 140° C. at about 1 to 3 bar of pressure. Here, the polymer layer 40 may employ the product called SURLYN manufactured by the company, Dupont.

Next, an electrolyte is injected in operation S50 between the lower and upper glass substrates 12 and 52 through a predetermined injection hole (not shown). The electrolyte may be a redox iodide electrolyte. According to an embodiment of the present invention, the electrolyte may be I₃⁻/I⁻ electrolyte obtained by dissolving 0.7 M 1-vinyl-3-hexyl-imidazolium iodide, 0.1M LiI, and 40 mM I₂(Iodine) in 3-Methoxyproionitrile. According to another embodiment of the present invention, the electrolyte may be an acetonitrile solution including 0.6M of butylmethylimidazolium, 0.02 M I₂, 0.1 M guanidinium thiocyanate, 0.5 M 4-tert-butylpyridine. However, one of various other electrolytes not exemplarily described may be used for the dye-sensitized solar cell of the present invention. For example, the electrolyte may include alkylimidazolium iodides or tetra-alkyl ammoniumiodides. The electrolyte may further include tert-butylpyridin (TBP), benzimidazole (BI), and N-Methylbenzimidazole (NMBI) as surface additives, and acetonitrile, propionitrile, or a mixed solution of acetonitrile and valeronitrile may be used as a solvent.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A dye-sensitized solar cell comprising:
a semiconductor electrode layer including hollow-shaped semiconductor particles; and
a dye layer adsorbed on a surface of the semiconductor electrode layer,
wherein the dye layer is adsorbed onto outer surfaces and inner surfaces of the semiconductor particles.

2. The dye-sensitized solar cell of claim 1, wherein the semiconductor particles have at least one shape selected from the group consisting of a hollow sphere, a hollow hemisphere, and a hollow sphere with a through-hole.

3. The dye-sensitized solar cell of claim 1, wherein the semiconductor particle comprises at least one through-hole connecting the outer surface and the inner surface thereof.

4. The dye-sensitized solar cell of claim 3, wherein the through-hole has a diameter greater than sizes of dye molecules forming the dye layer.

5. The dye-sensitized solar cell of claim 1, wherein the semiconductor particles respectively have a diameter ranging from about 10 nm to about 60 nm.

6. The dye-sensitized solar cell of claim 1, wherein the semiconductor electrode layer is formed of at least one selected from the group consisting of titanium oxide (TiO₂), tin oxide (SnO₂), zirconium oxide (ZrO₂), silicon oxide (SiO₂), magnesium oxide (MgO), niobium oxide (Nb₂O₅), and zinc oxide (ZnO).

7. The dye-sensitized solar cell of claim 1, wherein the dye layer is at least one of ruthenium complexes including N719, N712, Z907, Z910, and K19.

8. The dye-sensitized solar cell of claim 1, further comprising:
a lower electrode structure disposed under the semiconductor electrode layer;
an upper electrode structure disposed over the semiconductor electrode layer; and
an electrolyte interposed between the upper electrode structure and the semiconductor electrode layer,
wherein the lower electrode structure includes a lower substrate and a lower transparent electrode disposed on the lower substrate and contacting the semiconductor electrode layer, and
the upper electrode structure includes an upper substrate, an upper transparent electrode disposed on the upper substrate and facing the semiconductor electrode layer, and a catalyst layer interposed between the upper transparent electrode and the electrolyte.

9. A method for fabricating a dye-sensitized solar cell, comprising:
forming a lower electrode structure;
forming a semiconductor electrode layer including hollow-shaped semiconductor particles on the lower electrode structure;
forming a dye layer on a surface of the semiconductor electrode layer;
forming an upper electrode structure on a resultant structure including the dye layer such that the upper electrode structure faces the semiconductor electrode layer; and
injecting an electrolyte between the semiconductor electrode layer and the upper electrode structure.

10. The method of claim 9, wherein the forming of the semiconductor electrode layer comprises forming the hollow-shaped semiconductor particles with at least one of methods using a template, micro-emulsion, hydrolysis, and sol-gel synthesis.

11. The method of claim 10, wherein the forming of the semiconductor electrode layer further comprises forming at least one through-hole in each of the semiconductor particles to connect inner surfaces and outer surfaces of the semiconductor particles, the through-holes having diameters greater than dye molecules forming the dye layer, and
the dye layer is adsorbed on the outer surfaces of the semiconductor particles and the inner surfaces of the semiconductor particles through the through-holes.

12. The method of claim 11, wherein the forming of the through-holes comprises using at least one of heat treating, rapid drying, supersonic treating, and physical pressing techniques.

13. The method of claim 9, wherein the semiconductor particles have at least one shape selected from the group consisting of a hollow sphere, a hollow hemisphere, and a hollow sphere with a through-hole.

14. The method of claim 9, wherein the semiconductor electrode layer is formed of at least one selected from the group consisting of titanium oxide (TiO₂), tin oxide (SnO₂), zirconium oxide (ZrO₂), silicon oxide (SiO₂), magnesium oxide (MgO), niobium oxide (Nb₂O₅), and zinc oxide (ZnO).

15. The method of claim 9, wherein the semiconductor particles respectively have a diameter ranging from about 10 nm to about 60 nm.

16. The method of claim 9, wherein the dye layer is at least one of ruthenium complexes including N719, N712, Z907, Z910, and K19.

17. The method of claim 9, wherein the forming of the semiconductor electrode layer comprises:
forming spherical template particles;
forming a semiconductor material layer on surfaces of the template particles; and
forming voids in the semiconductor material layer by selectively removing the template particles.

18. The method of claim 17, wherein the template particles are formed of polystyrene.

19. The method of claim 17, further comprising, after the forming of the semiconductor material layer, forming at least one through-hole in each of the semiconductor particles by using at least one of a rapid thermal annealing process, a rapid drying process, a supersonic treatment process, and a physical pressing process, wherein the through-holes have diameters greater than dye molecules forming the dye layer and connects inner surfaces and outer surfaces of the semiconductor particle.

20. The method of claim 19, wherein the forming of the through-holes by using the rapid thermal annealing process is performed at a temperature ranging from about 450° C. to about 700° C.
